(19) United States
(12) Patent Application Publication
(10) Pub. No.: US 2017/0160320 A1
(43) Pub. Date: Jun. 8, 2017

(54) METHODS AND APPARATUSES FOR IDENTIFYING ANOMALY WITHIN SEALED PACKAGES USING POWER SIGNATURE ANALYSIS COUNTERFEITS

(71) Applicant: Power Fingerprinting Inc., Vienna, VA (US)

(72) Inventors: Carlos R. Aguayo Gonzalez, Reston, VA (US); Jeffrey H. Reed, Blacksburg, VA (US); Steven C. Chen, Potomac, MD (US)

(73) Assignee: Power Fingerprinting Inc., Vienna, VA (US)

(21) Appl. No.: 15/368,273

(22) Filed: Dec. 2, 2016

Related U.S. Application Data
(60) Provisional application No. 62/262,180, filed on Dec. 2, 2015.

(51) Int. Cl. G01R 23/02

(52) U.S. Cl. CPC G01R 23/02

(57) ABSTRACT

Some embodiments described herein include an apparatus having a memory and a processor operatively coupled to the memory. The processor is configured to receive, in response to an excitation signal and from the power signature detector, a power signature signal associated with a target electronic device disposed within a sealed package. The processor is configured to extract a characteristic of the power signature signal and compare the characteristic of the power signature signal with a characteristic of a reference power signature signal associated with at least one reference device to determine a counterfeit status of the target electronic device. The at least one reference device is a pre-determined trusted device or a pre-determined counterfeit device. The processor is configured to send, to a communication interface, a notification signal associated with the counterfeit status of the target electronic device.

### CROSS-REFERENCE TO RELATED APPLICATION

This application claims priority to U.S. Provisional Patent Application Ser. No. 62/262,180, filed on Dec. 2, 2015, the contents of which are incorporated herein by reference in its entirety.

This application is related to U.S. patent application Ser. No. 13/883,105, having a 35 U.S.C. §371(c) date of Aug. 15, 2013 (U.S. Pat. No. 9,262,632), entitled “Using Power Fingerprinting (PFP) To Monitor The Integrity And Enhance Security Of Computer Based Systems,” which is incorporated herein by reference in its entirety.

### BACKGROUND

Some embodiments described herein relate generally to methods and apparatus to use power signature techniques to identify counterfeit electronic devices within sealed packages.

Techniques such as X-ray scanning or terahertz scanning have been used to inspect sealed packages to determine if large contraband objects are disposed within the sealed packages. Using these known techniques to inspect packages that contain electronic devices with electronic components in a circuit, however, is difficult given the complexity of electronic devices. These known techniques do not provide insight into internal electronics within a device such that a counterfeit device or counterfeit components within an electronic device can be identified.

Accordingly, a need exists for methods and apparatus to identify counterfeit devices or counterfeit components within an electronic device disposed within a sealed package.

### SUMMARY

Some embodiments described herein include an apparatus having a memory and a processor operatively coupled to the memory. The processor is configured to be operatively coupled to a power signature detector. The processor is configured to receive, in response to an excitation signal and from the power signature detector, a power signature signal associated with a target electronic device disposed within a sealed package. The processor is configured to extract a characteristic of the power signature signal and compare the characteristic of the power signature signal with a characteristic of a reference power signature signal associated with at least one reference device to determine a counterfeit status of the target electronic device. The at least one reference device is a pre-determined trusted device or a pre-determined counterfeit device. The processor is configured to send, to a communication interface, a notification signal associated with the counterfeit status of the target electronic device.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a schematic diagram illustrating aspects of a package inspection system, according to an embodiment.

FIG. 2 is a schematic diagram illustrating a package inspection controller, according to an embodiment.

FIG. 3 is a flow chart illustrating a method to determine a counterfeit status of an electronic device disposed within a sealed package, according to an embodiment.

FIG. 4 is an experimental setup of a package inspection system, according to an embodiment.

FIG. 5 is a graph showing reflected electromagnetic emission signals from a pre-determined trusted device and a pre-determined counterfeit device, according to an embodiment.

FIG. 6 is a graph showing error signals between an expected response and an observed response for a pre-determined trusted device and a pre-determined counterfeit device, according to an embodiment.

FIG. 7 is a graph showing error distributions of a pre-determined trusted device and a pre-determined counterfeit device, according to an embodiment.

FIG. 8 is a flow chart showing a process of detector design, according to an embodiment.

FIG. 9 is a graph showing sample probability distribution from trusted code execution used for detector design and threshold selection, according to an embodiment.

### DETAILED DESCRIPTION

Some embodiments described herein include an apparatus having a memory and a processor operatively coupled to the memory. The processor is configured to be operatively coupled to a power signature detector. The processor is configured to receive, in response to an excitation signal and from the power signature detector, a power signature signal associated with a target electronic device disposed within a sealed package. The processor is configured to extract a characteristic of the power signature signal and compare the characteristic of the power signature signal with a characteristic of a reference power signature signal associated with at least one reference device to determine a counterfeit status of the target electronic device. The at least one reference device is a pre-determined trusted device or a pre-determined counterfeit device. The processor is configured to send, to a communication interface, a notification signal associated with the counterfeit status of the target electronic device.

As used herein, a module can be, for example, any assembly, instructions and/or set of operatively-coupled electrical components, and can include, for example, a memory, a processor, electrical traces, optical connectors, software (executing in hardware) and/or the like.

As used in this specification, the singular forms “a,” “an” and “the” include plural referents unless the context clearly dictates otherwise. Thus, for example, the term “a package” is intended to mean a single package or multiple packages. For another example, the term “a trace” can mean a single trace or multiple traces.

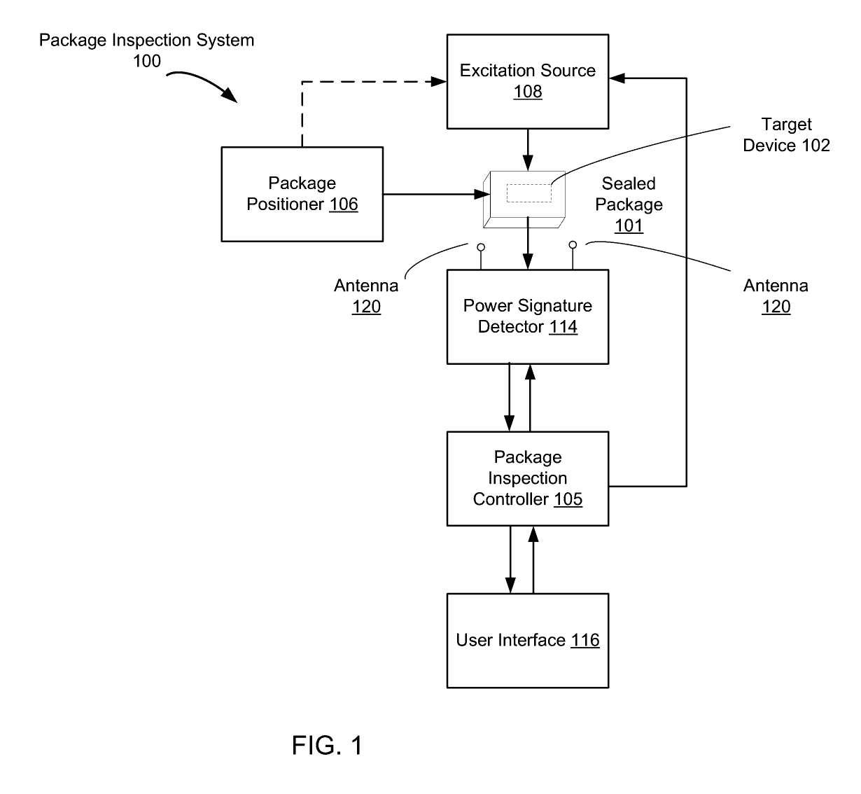

FIG. 1 is a schematic diagram illustrating aspects of a package inspection system 100 that can be configured to detect counterfeit, unauthorized modifications, non-functional, and/or tampered electronic circuits and/or devices (also referred to herein as counterfeit) such as critical embedded systems, coprocessors, and field-programmable gate arrays (FPGAs), according to one embodiment. The package inspection system 100 can be configured to detect counterfeit analog and/or digital circuits and/or devices. The package inspection system 100 can be configured to detect anomalies in hardware and/or software of the target circuits and/or devices. The package inspection system 100 can be implemented as a stand-alone apparatus, a portable apparatus, a point-and-detect apparatus, in a box, as a moveable belt system (e.g., a baggage screening system at an airport), and/or the like. As shown in FIG. 1, a package inspection system 100 includes a sealed package 101, a package positioner 106, an excitation source 108, a power signature detector 114, a package inspection controller 105, and a user interface 116. Note that FIG. 1 is a system block diagram, and therefore certain details are intentionally omitted to improve the clarity of the description.

The sealed package 101 can hold a target device(s) 102 within the package. The target device 102 can include electronic circuits such as chips, critical embedded systems, coprocessors, and field-programmable gate arrays (FPGAs). For example, the target device 102 can include computers, cell phones, digital cameras, tablets, electrical circuit boards, and/or electronic components. The target device 102 can include an analog electronic component(s) (e.g., an analog circuit(s)) and/or digital circuits. In some instances, the target device 102 can be sealed in a package. Thus, the orientation of a target device 102 may be unknown. In some instances, the target device 102 is not sealed in a package, and the orientation of the target device 102 is known and/or pre-determined. In other instances, an target device 102 is in a sealed package and the orientation of the target device 102 is known and/or pre-determined. For example, the orientation of a new target device in its original package is known and is the same from package to package. Although the discussion here is generally in the context of a single target device, it should be understood that multiple target devices can be analyzed simultaneously. The target device 102 disposed within the sealed package 101 is also referred to herein as an electronic device, a target electronic device, or a target.

A package positioner 106 can include an X-ray or terahertz scanner to determine an orientation of the target device 102 disposed within the sealed package 101. In some embodiments, the power signature signals (described below) can vary depending on the orientation of the target device 102. Therefore, the package positioner 106 can be configured to determine an orientation of the target device 102 and re-orientate the sealed package 101 to a desired orientation for testing. In some instances, the package positioner 106 can re-orientate the sealed package 101 through trial-and-error. In some instances, the package positioner 106 can include a positioner device to re-orientate the sealed package 101 such that the orientation of the target device 102 aligns with a pre-determined orientation for counterfeit inspection. In some instances, the package positioner 106 can include a second positioner device to re-orientate the excitation source 108 such that the orientation of the target device 102 aligns with a pre-determined orientation for counterfeit inspection. In some instances, the positioner device to re-orientate the sealed package 101 can be the same positioner device to re-orientate the excitation source 108. In other instances, the positioner device to re-orientate the sealed package 101 is different from the positioner device to re-orientate the excitation source 108. The positioner device to re-orientate the sealed package 101 and/or the excitation source 108 can include, for example, a X-Y table translator that can move the sealed package 101 and/or the excitation source 108 in the x and y directions. The positioner device to re-orientate the sealed package 101 and/or the excitation source 108 can also include, for example, a rotary table that can rotate the sealed package 101 and/or the excitation source 108 in the x-y plane. The positioner device to re-orientate the sealed package 101 and/or the excitation source 108 can also include a motor to translate and/or rotate the sealed package 101 and/or the excitation source 108.

The excitation source 108 can emit an excitation signal which can be, for example, a Radio Frequency (RF) signal, an electromagnetic interference (EMI) pulse, a white noise signal, a wide-band signal, and/or a frequency-swept signal. In some instances, the excitation source 108 can be controlled and/or adjusted by the package inspection controller 105 via the user interface 116. In other instances, the excitation source 108 is controlled via a separate controller.

The power signature detector 114 can be configured to receive a power signature signal of the target device 102 when the target device 102 responds to an excitation signal emitted by the excitation source 108. In some embodiments, the power signature detector 114 includes a set of antennas 120, an amplifier (not shown), and a digitizer (e.g., an analog-to-digital Converter (ADC) not shown). When the target device 102 in the sealed package 101 is excited by the excitation signal (or under a frequency sweep), electromagnetic (EM) signals are reflected, and/or absorbed by the target device 102, as well as harmonics are produced by the target device 102 interacting with the excitation source. The antennas 120 in the power signature detector 114 can receive electromagnetic (EM) emission signals attenuated, induced and/or reflected from the target electronic device 102 under excitation. The antennas 120 can also measure other physical signals (e.g., temperature, vibration, and/or the like) associated with the target device 102 under excitation. The measurement of the power signature signal during the excitation from the external excitation source 108 can be performed when the target device 102 is operating (e.g., locally powered on) or when the target device 102 is not operating (e.g., locally powered off). The antennas 120 can send the power signature signals (e.g., the EM emission signals and other physical signals such as temperature, vibration and/or the like) to the amplifier (not shown). The amplifier (not shown) in the power signature detector 114 can be configured to amplify the power signature signals received by the antennas 120, which can be digitalized processed by the digitizer (not shown) in the power signature detector 114.

In another embodiment, the power signature detector 114 includes a set of antennas 120 to receive the EM signals from the target electronic device 102 under excitation. The set of antennas 120 can be spatially distributed in a plane substantially parallel to a plane of the sealed package 101, or substantially perpendicular to the plane of the sealed package 101. In some instances, the set of antennas 120 can be spatially distributed in the plane substantially parallel to the plane of the sealed package 101 and in the plane substantially perpendicular to the plane of the sealed package 101. In use, instead of the package positioner 106 determining the orientation of the target device 102 and re-orientate the target device 102 to a desired (or pre-determined) orientation for testing, a particular antenna from the set of antennas 120 can be selected depending on the desired (or pre-determined) physical relationship between the target device 102 and the selected antenna 120. For example, if the sealed package 101 is oriented vertically, a set of antennas 120 can be spatially distributed in a plane substantially perpendicular to the plane of the sealed package 101. In other words, the set of antennas 120 are placed around the sealed package 101 at 12 o'clock, 3 o'clock, 6 o'clock and 9 o'clock. If, for example, the sealed package 101 needs be oriented differently by 90 degrees counterclockwise (e.g., from the 12 o'clock antenna), in one instance, the package positioner 106 can rotate the sealed package 101 by 90 degrees counterclockwise and use the 12 o'clock antenna to measure the power signature signal. In another instance, the sealed package 101 does not need to be moved and the 3 o'clock antenna can be used instead to measure the power signature signal.

The package inspection controller 105 can be configured to control and/or adjust parameters of the excitation source 108. The adjustable parameters of the excitation source 108 include at least one of frequency bandwidth, frequency modulation, amplitude modulation, duration, incident angle, and/or power. The package inspection controller 105 can also control the power signature detector 114 for better detection of the power signature signals. In some embodiments, the package inspection controller 105 can adjust parameters of the power signature detector 114 to substantially match that of the excitation source 108. For example, the package inspection controller 105 can adjust the power signature detector 114 such that the frequency bandwidth, duration, and modulation of the power signature detector 114 match (or substantially match) those of the excitation source 108.

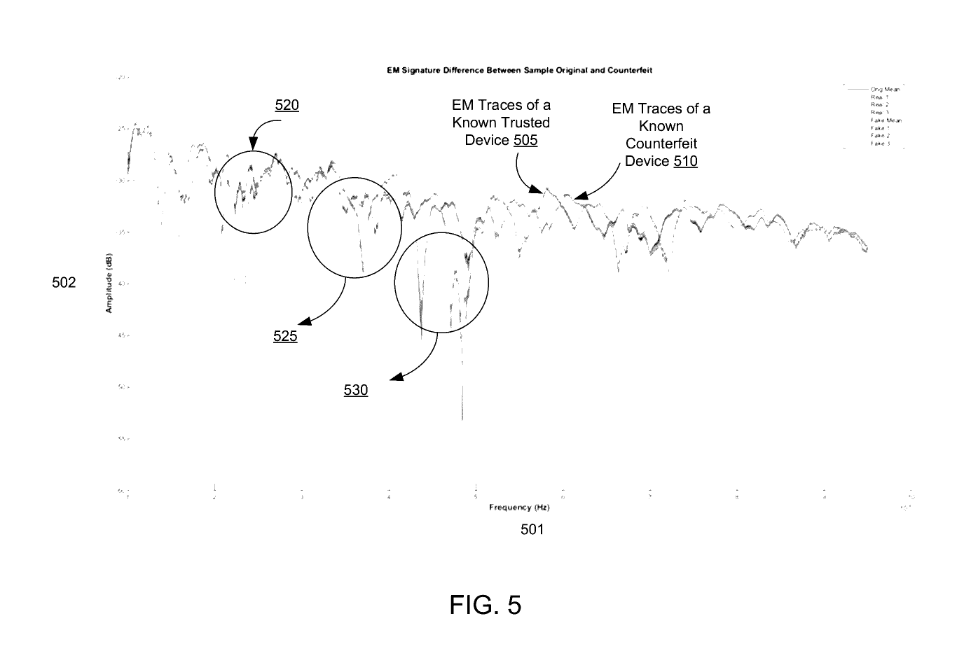

The package inspection controller 105 can process the power signature signals (also referred herein to as test signals or test traces) received from the power signature detector 114 and perform power signature analysis to determine a counterfeit status of the target device 102. In some embodiments, the package inspection controller 105 can perform different signal processing approaches to extract discriminatory features (also referred herein to as characteristics) from the power signature signals captured by the power signature detector 114 that uniquely identify the EM emission (and therefore the counterfeit status) of the target device 102. Feature extraction can involve analysis in resonance frequencies, absorption frequencies, polarization, harmonic reflections, reflection arrival times, and/or signal strength. Details of the feature extraction process are discussed herein with regards to FIGS. 5-7.

The package inspection controller 105 can retrieve reference power signature data associated with reference devices (e.g., pre-determined trusted devices and/or pre-determined counterfeit devices) from a power signature reference database (not shown in FIG. 1). The package inspection controller 105 can compare the reference power signature signals of the reference devices with the power signature signals of the target device 102. In some instances, these reference power signature data can be extracted during characterization processes (e.g., performed before assessment of the target device 102 in sealed package 101) on reference devices (e.g., pre-determined trusted devices and/or pre-determined counterfeit devices) in a certain (or pre-determined) orientation. The target device 102 can be tested in the same (or substantially the same) orientation as the orientation of the reference devices. Therefore, the reference power signature signals of the reference devices in a pre-determined orientation can be compared with the power signature signals from the target device 102 in the same orientation (or substantially same orientation, which is a range in which the power signature signals of the target device(s) 102 are sufficiently correlated with the reference power signature signals of the reference devices.) In other instances, the reference power signature signals can be extracted during characterization processes on reference devices in a set of orientations. The target device 102, in these circumstances, can be tested in any orientation. The received power signature signals from the target device 102 in an orientation can be compared with the reference power signature signals of reference devices in each orientation of the set of orientations.

There are several options to facilitate and enhance the generation of reference power signature data including: crowd sourcing (e.g., by obtaining numerous references from multiple sources to define what is a power signature of a reference device), machine learning in the field (repeated observations of a power trace to define what historically constitutes a power signature of a reference device), and/or the like. For example, the reference power signature data generation can include crowd source pre-determined counterfeit devices. When a number of pre-determined counterfeit devices are deployed, a baseline reference power signature signal can be generated and a comparison between the power signature signal of the target device 102 and the baseline reference power signature signal of the reference devices can be subsequently performed. In some embodiments, these reference power signature data can be updated when a new device in the product line of the reference devices is released. Reference power signature data may be stored locally at the package inspection controller 105 or remotely from the package inspection controller 105.

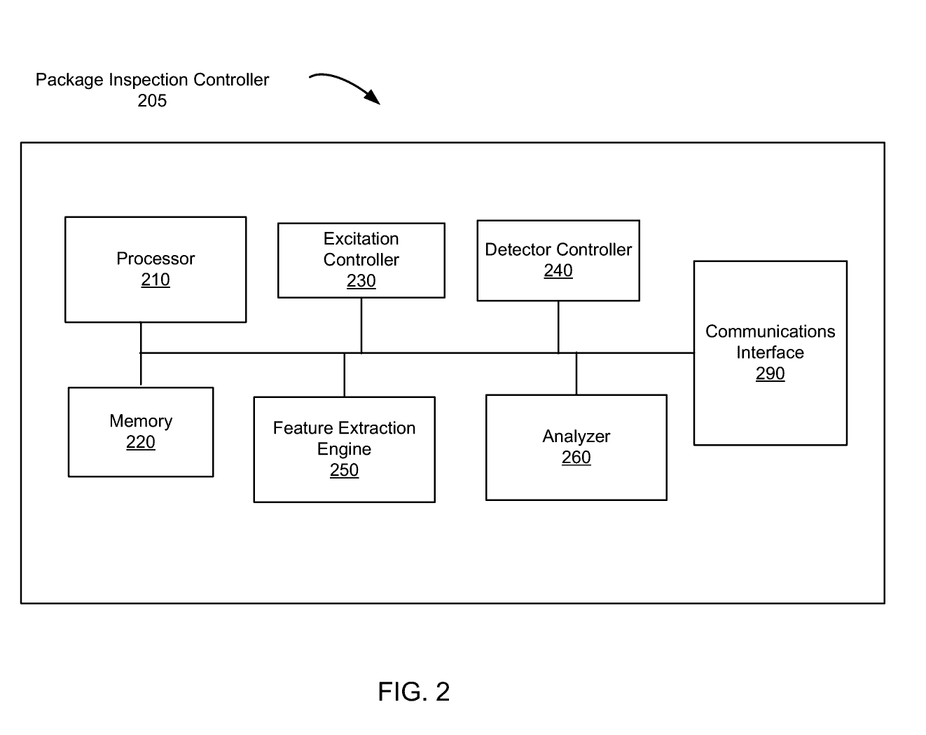

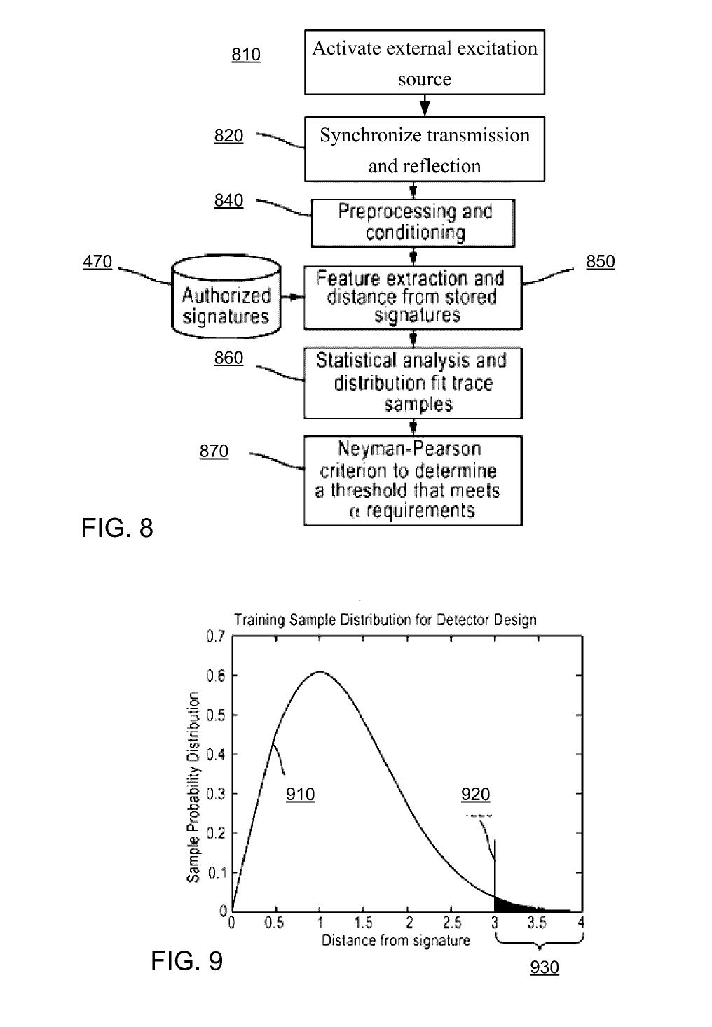

Once the characteristics have been selected based on the power signature signal of the target device 102 and the reference power signature signal from the reference devices have been retrieved, the package inspection controller 105 can compare the selected characteristics of the power signature signal with a characteristic of the reference power signature signal. In some embodiments, a set of power signature signals of the target device 102 can be collected and compared with a set of reference power signature signals. In some instances, a statistical analysis of the comparison between power signature signals and the reference power signature signals can provide a probability distribution with error deviation with regards to the counterfeit status of the target device 102. Details of the analysis methods are discussed herein with regards to FIGS. 8-10. Upon performing the comparison and the analysis, the package inspection controller 105 can determine a counterfeit status (or a probability of a counterfeit status) of the target electronic device(s) 102 disposed within the sealed package 101. Further details of the package inspection controller 105 are discussed with respect to FIG. 2.

In some instances, the package inspection controller 105 can send, via a user interface 116, a notification signal (or a user alert) associated with the determined counterfeit status of the target device 102. A user can control the package inspection controller 105 via the user interface 116 (e.g., a GUI (graphic user interface)). The user interface 116 can be implemented at a user device (e.g., a monitor, keyboard, touch screen, compute device, etc.) associated with the package inspection controller 105. In other embodiments, the sealed package 101 can be diverted for further inspection. The user interface 116 is not limited to dashboard (status of target device or system under test), interfaces that collect user input, user configuration, user-set trust level (e.g., thresholds for detection and statistical metrics), general operating statistics (e.g., number of counterfeit detection, uptime, trends), and/or the like. The user interface 116 can be configured to communicate to a communication interface of the package inspection controller 105 (such as the communication interface 290 of the package inspection controller 205 described below with regards to FIG. 2) to receive the notification signal associated with the counterfeit status of the target device 102.

FIG. 2 is a schematic diagram illustrating a package inspection controller 205, according to an embodiment. The package inspection controller 205 can be structurally and functionally similar to the package inspection controller 105 shown and described with respect to FIG. 1. The package inspection controller 205 includes a processor 210, a memory 220, a communications interface 290, an excitation controller 230, a detector controller 240, a feature extraction engine 250, and an analyzer 260. In some embodiments, the package inspection controller 205 can be a single physical device. In other embodiments, the package inspection controller 205 can include multiple physical devices (e.g., operatively coupled by a network), each of which can include one or multiple modules and/or components shown in FIG. 2.

Each module or component in the package inspection controller 205 can be operatively coupled to each remaining module and/or component. Each module and/or component in the package inspection controller 205 can be any combination of hardware and/or software (stored and/or executing in hardware) capable of performing one or more specific functions associated with that module and/or component.

The memory 220 can be, for example, a random-access memory (RAM) (e.g., a dynamic RAM, a static RAM), a flash memory, a removable memory, a hard drive, a database and/or so forth. In some embodiments, the memory 220 can include, for example, a database, process, application, virtual machine, and/or some other software modules (stored and/or executing in hardware) or hardware modules configured to execute a package inspection process and/or one or more associated methods for package inspection. In such embodiments, instructions of executing the package inspection process and/or the associated methods can be stored within the memory 220 and executed at the processor 210. In some embodiments, power signature data of a target device and/or reference power signature data of reference devices can be stored in the memory 220.

The communications interface 290 can include and/or be configured to manage one or multiple ports of the package inspection controller 205. In some instances, for example, the communications interface 290 (e.g., a Network Interface Card (NIC)) can be operatively coupled to devices (e.g., user input devices not shown in FIG. 2) and can actively communicate with a coupled device or over a network (e.g., communicate with end-user devices, host devices, servers, etc.). The communication network can be any network or combination of networks capable of transmitting information (e.g., data and/or signals) and can include, for example, a telephone network, an Ethernet network, a fiber-optic network, a wireless network, and/or a cellular network. The communication can be over a network such as, for example, a Wi-Fi or wireless local area network (“WLAN”) connection, a wireless wide area network (“WWAN”) connection, and/or a cellular connection. A network connection can be a wired connection such as, for example, an Ethernet connection, a digital subscription line (“DSL”) connection, a broadband coaxial connection, and/or a fiber-optic connection. In some embodiments, the communications interface 290 can be configured to, among other functions, receive data and/or information, and send package inspection modifications, commands, and/or instructions.

The processor 210 can be configured to control, for example, the operations of the communications interface 290, write data into and read data from the memory 220, and execute the instructions stored within the memory 220. The processor 210 can also be configured to execute and/or control, for example, the operations of the excitation controller 230, the detector controller 240, the feature extraction engine 250, and the analyzer 260, as described in further detail herein. In some embodiments, under the control of the processor 210 and based on the methods or processes stored within the memory 220, the excitation controller 230, the detector controller 240, the feature extraction engine 250, and the analyzer 260 can be configured to execute a package inspection process, as described in further detail herein.

The excitation controller 230 can be any hardware and/or software module (e.g., stored in a memory such as the memory 220 and/or executing in hardware such as the processor 210) configured to control and/or adjust parameters of the excitation source 108. The adjustable parameters of the excitation source 108 include at least one of frequency bandwidth, modulation, duration, incident angle, polarization, and/or power of an excitation signal. The excitation signal can be, for example, a Radio Frequency (RF) signal, an electromagnetic interference (EMI) pulse, a white noise signal, a wide-band signal, and/or a frequency-swept signal.

The detector controller 240 can be any hardware and/or software module (e.g., stored in a memory such as the memory 220 and/or executing in hardware such as the processor 210) configured to control and/or adjust parameters of the power signature detector 114 for better detection of power signature signals of the target device 102. In some embodiments, the detector controller 240 can adjust parameters of the power signature detector 114 to match that of the excitation source 108. For example, the detector controller 240 can adjust the power signature detector 114 such that the frequency bandwidth, duration, and modulation of the power signature detector 114 are the same (or substantially the same) as those of the excitation source 108. Such synchronization between the power signature detector 114 and the excitation source 108 allows for harmonic reflections due to solid state components or dissimilar metal contacts.

The feature extraction engine 250 can be any hardware and/or software module (e.g., stored in a memory such as the memory 220 and/or executing in hardware such as the processor 210) configured to prepare the received power signature signals of the target device 102 to be compared with the reference power signature signals of reference devices. The feature extraction engine 250 can condition the power signature signals (or traces) to extract the selected discriminatory features (or characteristics), e.g. converting the traces to the appropriate domain (such as time domain and/or frequency domain), or aligning the traces in reference to a specific marker. Details of the feature extraction process are discussed herein with regards to FIGS. 5-7.

The analyzer 260 can be any hardware and/or software module (stored in a memory such as the memory 220 and/or executing in hardware such as the processor 210) configured to determine whether a target device or an electronic component within a target device should be considered a counterfeit. The excitation controller 230, the detector controller 240, the feature extraction engine 250, and the analyzer 260 can be implemented at the same memory and/or the processor, or separate memories and/or processors.

Once the power signature signals from the target devices are captured and characteristics are selected, the analyzer 260 can compare the characteristics of the power signature signals with characteristics of reference power signature signals associated with reference devices (e.g., pre-determined trusted devices or predetermined counterfeit devices). In some instances, these reference power signature signals can be extracted during characterization processes on reference device(s) while in a pre-determined orientation. The target device can be tested in the same (or substantially the same) orientation as the orientation of the reference devices. Therefore, the reference power signature signals in a pre-determined orientation can be compared with the received power signature signals of the target device in the same (or substantially the same) orientation. In other instances, the reference power signature signals can be extracted during characterization processes on reference devices in a set of orientations. The target device, in these circumstances, can be tested in any orientation. The received power signature signals of the target device in an orientation can be compared with the reference power signature signals in each orientation of the set of orientations.

In some embodiments, the analyzer 260 can compare a set of power signature signals of the target device with a set of reference power signature signals. In some instances, the analyzer 260 can conduct a statistical analysis of the comparison between target power signature signals and the reference power signature signals and determine a probability distribution with error deviation with regards to the counterfeit status of the target device. Details of the analysis methods are discussed herein with regards to FIGS. 8-9. Upon performing comparison and analytics, the analyzer 260 can determine a counterfeit status (or a probability of a counterfeit status) of the target electronic device(s) disposed within the sealed package.

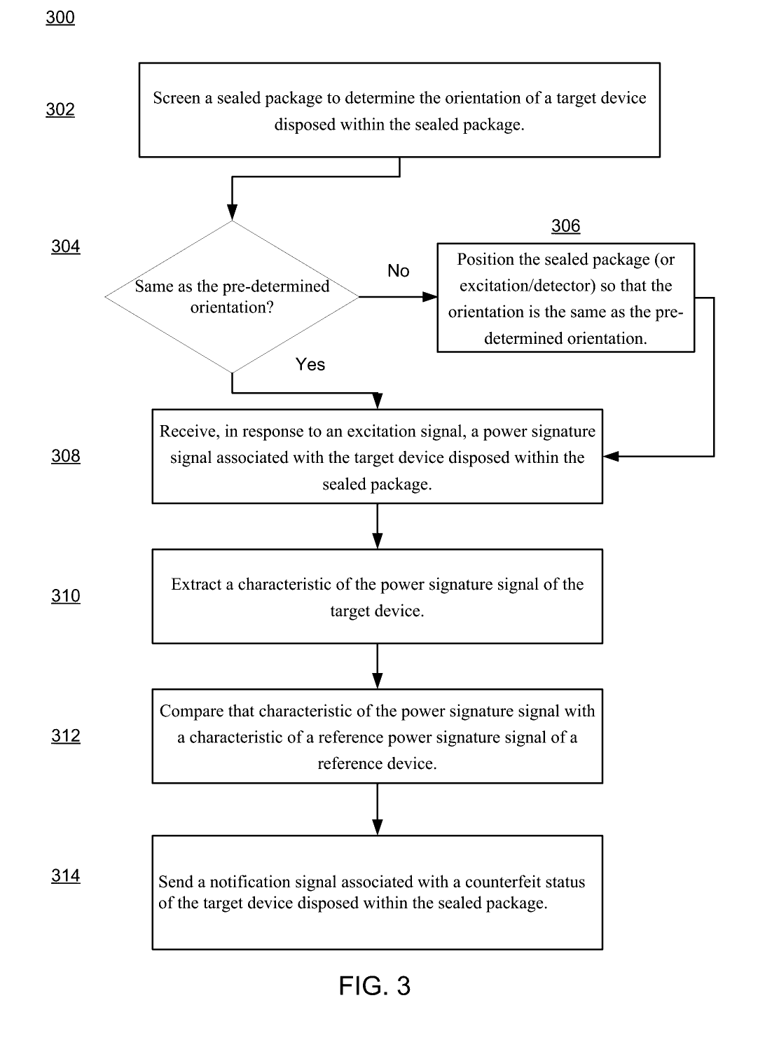

FIG. 3 is a flow chart illustrating a method 300 to detect a counterfeit status of an electronic device disposed within a sealed package, according to an embodiment. The counterfeit status includes any counterfeit, unauthorized modifications, non-functional, and/or tampered electronic circuits and/or devices disposed within a sealed package, according to one embodiment. The package inspection method 300 can be executed at, for example, a package inspection system such as the package inspection system 100 shown and described with respect to FIG. 1. In some embodiments, a package positioner in the package inspection system screens a sealed package to determine the orientation of a target device disposed within the sealed package at 302. If the orientation of the target device is the same (or substantially the same) as a pre-determined orientation at 304, a power signature detector in the package inspection system receives a power signature signal of the target device disposed within the sealed package at 308. If the orientation of the target device is different from the pre-determined orientation at 304, the package positioner re-orientates the sealed package such that the orientation of the target device is the same (or substantially the same) as the pre-determined orientation at 306. The pre-determined orientation can be an orientation in which reference power signature signals of reference devices (e.g., pre-determined trusted devices or pre-determined counterfeit devices) are captured such that the power signature signals of the target device can be compared with the reference power signature signals in the same (or substantially the same) orientation. In some embodiments, the target device can be tested in each possible orientation. The power signature signals in each possible orientation can be compared to reference power signature signals and the power signature signals that has the best match with the reference power signature signals is selected for comparison and analysis for counterfeit inspection. In other embodiments, the target device can be tested in one orientation, while the reference power signature signals are collected from reference devices in each possible orientation. The power signature signals of the target device in the one orientation are compared with the reference power signature signals in each possible orientation, and the reference power signature signals that has the best match with the power signature signals is selected for comparison and analysis for counterfeit inspection.

Once the power signature signal of the target device is received at 308, a feature extraction engine in a package inspection controller in the package inspection system extracts a characteristic (also referred herein to as discriminatory feature) of the received power signature signal at 310. An analyzer in the package inspection controller compares that characteristic from the target device to a characteristic of a reference power signature signal from a reference device at 312 and determines a counterfeit status (or a probability of a counterfeit status) of the target electronic device(s) disposed within the sealed package. The package inspection controller can send, to a user interface, a notification signal associated with the counterfeit status of the target device based on the comparison of the characteristic of the power signature signal of the target device and the characteristic of the reference power signature signal from the reference device at 314.

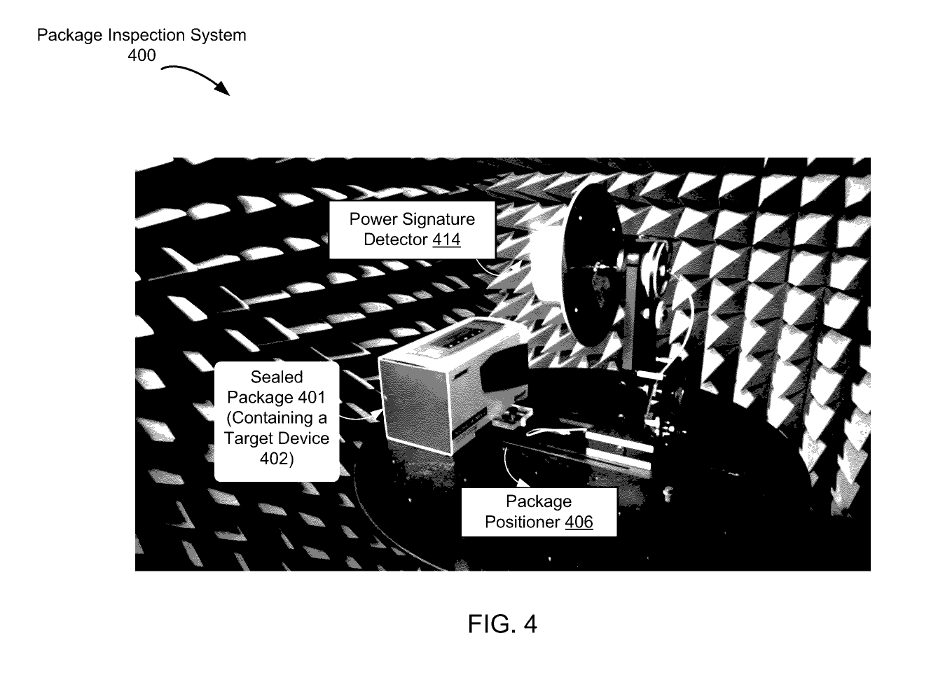

FIG. 4 is an experimental setup of a package inspection system, according to an embodiment. The package inspection system 400 is functionally and physically similar to the package inspection system 100 described in FIG. 1. The package inspection system 400 includes a sealed package 401 containing a target device 402, a package positioner 406, an excitation source (not shown in the figure), a power signature detector 414, and a package inspection controller (not shown in figure in FIG. 4). As discussed above with regards to FIG. 1, the target device 402 is sealed in a package 401, and thus, the orientation of the target device 402 may be unknown. The package positioner 406 can determine an orientation of the target device 402 and re-orientate the target device 402 to a pre-determined orientation for counterfeit inspection. The power signature detector 414 receives power signature signals (e.g., reflected EM signals) of the target device 402 excited by an excitation source. The package inspection controller can be operatively coupled to the power signature detector 414 to control and/or adjust parameters of the excitation source and the power signature detector 414. The package inspection controller can further process the power signature signals, and perform power signature analysis to determine a counterfeit status of the target device 402.

### Power Signature Analysis

A power signature analysis system, such as the package inspection controller 105 shown in FIG. 1, comprises three main elements common to all pattern recognition systems: sensing, feature extraction, and detection/classification. Power signature signals can be collected from an electronic device when the electronic device is operating (e.g., locally powered on) and/or when the electronic device is not operating (e.g., locally powered off). In some embodiments, when an excitation source, for example a Radio Frequency (RF) emitter, an electromagnetic interference (EMI) pulse, a white noise signal, a wide-band signal, and/or a frequency-swept signal, is applied to a target electronic device, an electromagnetic field(s) and/or wave(s) can be induced, reflected back, and/or absorbed by the target electronic device. Power is altered during the reflection of the EM field and/or wave(s) by the target electronic device. The propagated EM signals (thus the renewed power) vary depending on the integrity of the integrated circuits and/or electronic components within the target electronic device. In some instances, different components within the electronic device (such as processors, memories, circuit boards, etc.) can have different propagated EM signals (thus the received power). In some instances, when the components within the target electronic device are trusted components, the propagated EM signals (thus the received power) can vary based on the design (or arrangement) of the components within the target electronic device, which can indicate the counterfeit status of the target electronic device. Therefore, by measuring the propagated EM signals (or emission signals) from a target electronic device and comparing that with reference power signature signals from reference device(s) (e.g., pre-determined trusted devices, and/or pre-determine counterfeit devices), the integrity of the integrated circuits and/or electronic components within the target electronic device (e.g., the counterfeit status of the target electronic device) can be determined.

### Characterization

The characterization process involves collecting and characterizing reference power signature signals of reference devices by repeatedly applying excitation to the reference devices (e.g., pre-determined trusted devices, and/or pre-determined counterfeit devices) in a controlled environment (including setting inputs used during excitation, and helping synchronizing traces). For better performance, the characterization should be an iterative, interdependent process. There are several options to facilitate and enhance the generation of reference power signature data including: crowd sourcing (e.g., by obtaining numerous references from multiple sources to define what is a power signature of a reference device), machine learning in the field (repeated observations of a power trace to define what historically constitutes a power signature of a reference device), and/or the like. For example, the reference power signature data generation can include crowd source pre-determined counterfeit devices.

### Trace Processing And Feature Extraction

The process of preparing test traces (i.e., power signature signals of target devices) to be compared with the stored reference power signature signals is referred to herein as preprocessing and feature extraction. Trace preprocessing involves general tasks to condition the traces to extract the selected discriminatory features (or characteristics), e.g., converting the traces to the appropriate domain or aligning the traces in reference to a specific marker.

Another example of basic preprocessing is to align time-domain traces before being passed to a correlation detector. Time alignment of traces can be achieved with a correlation detector. In some instances, the correlation detector can be disposed within a package inspection controller such as the package inspection controller 105 in FIG. 1 or the package inspection controller 205 in FIG. 2. The correlation detector can be any hardware and/or software module (stored in a memory such as the memory 220 in FIG. 2 and/or executing in hardware such as the processor 210 in FIG. 2).

In this example, each trace of N samples is considered as a point in a multidimensional Euclidean space. Feature extraction is the process of calculating the final test statistic (or discriminatory feature) from new traces which is passed to the detectors and used to determine integrity. This process is unique to each selected feature. For example, in basic time domain correlation analysis, preprocessing could include coarse synchronization and compensation for specific platform or packaging characteristics, while feature extraction involves comparing against the stored signature by calculating the correlation factor or the Euclidean distance.

For example, FIG. 5 is a graph showing measured electromagnetic (EM) emission signals (also referred to herein as “traces”) from a pre-determined (or known) trusted device and a pre-determined (or known) counterfeit device, according to an embodiment. A set of EM traces measured from a known trusted device 505 at different times shows amplitude changes 502 over frequency 501. A set of EM traces measured from a known counterfeit device 510 at different times shows amplitude changes 502 over frequency 501. The set of EM traces from the known counterfeit device 510, however, exhibits behaviors distinct from the behaviors of the set of EM traces from the known trusted device 505.

As shown in FIG. 5, the set of EM traces from the known trusted device 505 and the set of EM traces from the known counterfeit device 510 have been preprocessed. Specifically, the EM traces, 505 and 510, have been converted to the frequency domain 501. The set of EM traces from the known trusted device 505 and the set of EM traces from the known counterfeit device 510 have also been synchronized for the following feature extraction. Feature extraction involves extracting discriminatory features from the two sets of EM traces and comparing the discriminatory features to determine if a device is a counterfeit device. As shown in FIG. 5, discriminatory features at, for example, 520, 525, and 530 from the two sets of EM traces can be desirable to extract because they show distinct divergences between the two sets of EM traces.

In use, a target device with unknown counterfeit status can be measured in a package inspection system (such as the package inspection systems 100 and 400 in FIGS. 1 and 4, respectively). A set of EM traces from the target device can be compared with a set of EM traces from a known trusted device. If no substantial divergence is found between the discriminatory features of the set of EM traces from the target device and the known trusted device, the target device can be determined to be trusted. On the other hand, if significant divergence (e.g., divergence exceeding a predefined threshold) is found between the discriminatory features of the set of EM traces from the target device and the known trusted device, the target device can be determined (or identified) to be a counterfeit device. Moreover, the set of EM traces from the target device can be compared with a set of EM traces from a known counterfeit device. If no significant divergence (e.g., divergence exceeding a predefined threshold) is found between the discriminatory features of the set of EM traces from the target device and the known counterfeit device, the target device can be determined to be counterfeit. On the other hand, similarly, if significant divergence is found between the discriminatory features of the set of EM traces from the target device and the known counterfeit device, the package inspection system can proceed to compare the EM traces from the target device with the EM traces from other known counterfeit devices until a determination, with certain confidence level, on the counterfeit status of the target device can be made.

### Detector Characteristics

Once the power signature signals have been extracted and the discriminatory features have been selected, the next step in the power signature analysis process is to design optimal detectors (such as the power signature detector 114 in FIG. 1) to perform the final integrity assessment. In some embodiments, the detector design is performed in advance to the package inspection process (such as the package inspection process described in FIG. 3) such that the reference data from the pre-determined trusted devices (and/or pre-determined counterfeit devices) have been collected and processed prior to testing the target electronic devices. These detectors can make the final decision of whether a target electronic device should be considered a counterfeit. The process of detector design and normal monitoring operation are very similar. In detector design, the EM emission signals from the pre-determined trusted devices (and/or pre-determined counterfeit devices) are captured and processed to extract the selected discriminatory features and compared against the stored signatures. Several traces are collected and processed and their statistical sample distributions are used to identify a threshold that yields the expected performance targets.

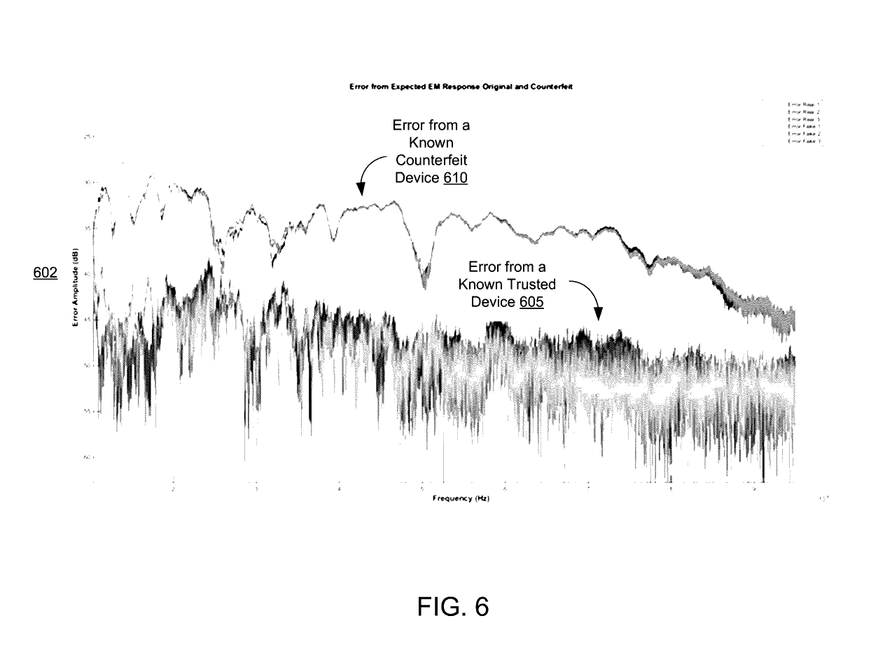

FIG. 6 is a graph showing error signals between an expected response and an observed response for a known trusted device and a known counterfeit device, according to an embodiment. The graph shows the error amplitude in dBs 602 of the reflected EM traces measured from the known trusted device 605 and the counterfeit device 610, versus frequency in Hz. As FIG. 6 shows, the error signals 602 for the known counterfeit device 610 are separated from the error signals 602 for the known trusted device 605, allowing for identification of other counterfeit devices, distinct from the known trusted device 605, according to the apparatus and method described herein.

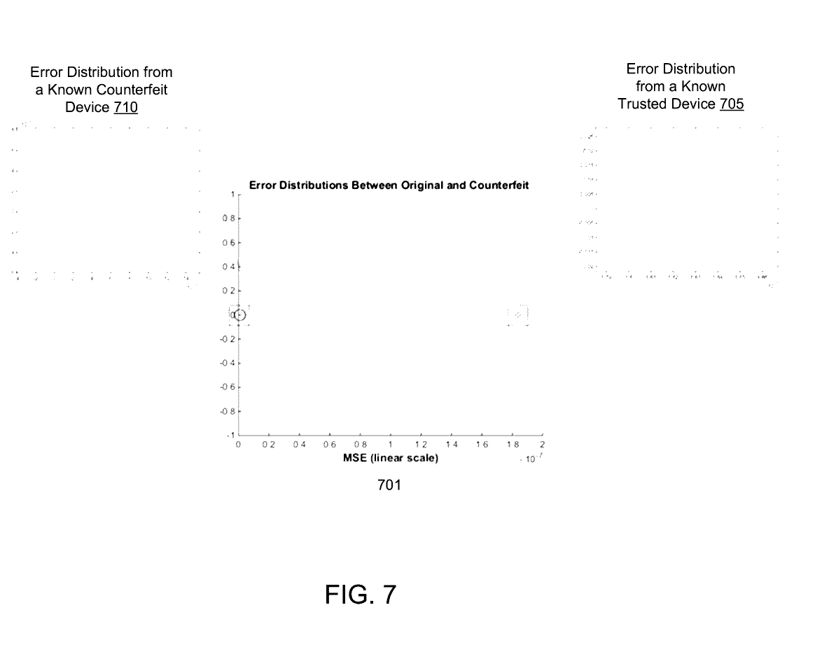

FIG. 7 is a graph showing error distributions of a known trusted device 705 and a known counterfeit device 710, according to an embodiment. Using a difference vector, the final test statistic or discriminatory feature passed to the detector can be represented by the mean squared error (MSE) 701 or any other distance or error metric. Several traces are collected and processed and their statistical sample distributions are used to identify a threshold that yields the expected performance targets. Again, due to the separation between the error distribution for the known counterfeit device 710 and the error distribution for the known trusted device 705, identification of other counterfeit devices, distinct from the known trusted device 605 can be performed.

An example of the process of detector design is shown in FIG. 8. An external excitation source is activated at 810. The parameters of the excitation source and the power signature detector are synchronized at 820, and the traces are preprocessed and conditioned at 840. Using authorized signatures at 470 for comparison, the selected discriminatory features are extracted and a distance metric is generated at 850. Then statistical analysis and distribution fitting is done at 860 on the resulting metrics. Finally, the Neyman-Pearson criterion is applied at 870 to determine a threshold that meets expected performance targets.

A common approach to design optimal detectors involves the application of the Neyman-Pearson criterion to maximize the probability of detection for a given probability of false alarm. As a brief reminder of this criterion, which is spawned from basic hypothesis testing theory, a target probability of false alarm is set based on the tolerance and estimated cost of making a mistake in the final decision. Using an estimate of the probability distribution of the discriminatory features from the pre-determined trusted devices (and/or pre-determined counterfeit devices), a distance threshold is calculated that yields the expected probability of false alarm while maximizing the probability of correct detection. An example of this process is shown in FIG. 9, in which a distance threshold 920 is calculated for a probability distribution 910 that yields an expected probability of false alarms 930.

There are different techniques that can yield improved results depending on the nature of the selected discriminatory features. Other techniques for detector design and machine training include: Neural Networks, Support Vector Machines, and Hidden Markov Models.

It is intended that the systems and methods described herein can be performed by software (stored in memory and/or executed on hardware), hardware, or a combination thereof. Hardware modules may include, for example, a general-purpose processor, a field programmable gate array (FPGA), and/or an application specific integrated circuit (ASIC). Software modules (executed on hardware) can be expressed in a variety of software languages (e.g., computer code), including Unix utilities, C, C++, Java™, JavaScript (e.g., ECMAScript 6), Ruby, SQL, SAS®, the R programming language/software environment, Visual Basic™, and other object-oriented, procedural, or other programming language and development tools. Examples of computer code include, but are not limited to, micro-code or micro-instructions, machine instructions, such as produced by a compiler, code used to produce a web service, and files containing higher-level instructions that are executed by a computer using an interpreter. Additional examples of computer code include, but are not limited to, control signals, encrypted code, and compressed code.

Some embodiments described herein relate to devices with a non-transitory computer-readable medium (also can be referred to as a non-transitory processor-readable medium or memory) having instructions or computer code thereon for performing various computer-implemented operations. The computer-readable medium (or processor-readable medium) is non-transitory in the sense that it does not include transitory propagating signals per se (e.g., a propagating electromagnetic wave carrying information on a transmission medium such as space or a cable). The media and computer code (also can be referred to as code) may be those designed and constructed for the specific purpose or purposes. Examples of non-transitory computer-readable media include, but are not limited to: magnetic storage media such as hard disks, floppy disks, and magnetic tape; optical storage media such as Compact Disc/Digital Video Discs (CD/DVDs), Compact Disc-Read Only Memories (CD-ROMs), and holographic devices; magneto-optical storage media such as optical disks; carrier wave signal processing modules; and hardware devices that are specially configured to store and execute program code, such as Application-Specific Integrated Circuits (ASICs), Programmable Logic Devices (PLDs), Read-Only Memory (ROM) and Random-Access Memory (RAM) devices. Other embodiments described herein relate to a computer program product, which can include, for example, the instructions and/or computer code discussed herein. Each of the devices described herein, for example, the excitation controller 230, the detector controller 240, the feature extraction engine 250, and the analyzer 260, can include one or more memories and/or computer readable media as described above.

While various embodiments have been described above, it should be understood that they have been presented by way of example only, and not limitation. Where methods and steps described above indicate certain events occurring in certain order, the ordering of certain steps may be modified. Additionally, certain of the steps may be performed concurrently in a parallel process when possible, as well as performed sequentially as described above. Although various embodiments have been described as having particular features and/or combinations of components, other embodiments are possible having any combination or sub-combination of any features and/or components from any of the embodiments described herein. Furthermore, although various embodiments are described as having a particular entity associated with a particular compute device, in other embodiments different entities can be associated with other and/or different compute devices.

What is claimed is:

1. An apparatus, comprising:
a memory; and
a processor operatively coupled to the memory and configured to be operatively coupled to a power signature detector, the processor configured to receive, in response to an excitation signal and from the power signature detector, a power signature signal associated with a target electronic device disposed within a sealed package,
the processor configured to extract a characteristic of the power signature signal and compare the characteristic of the power signature signal with a characteristic of a reference power signature signal associated with at least one reference device to determine a counterfeit status of the target electronic device, the at least one reference device being a pre-determined trusted device or a pre-determined counterfeit device,
the processor configured to send, to a communication interface, a notification signal associated with the counterfeit status of the target electronic device.

2. The apparatus of claim 1, wherein the target electronic device includes an analog electronic component.

3. The apparatus of claim 1, wherein the processor is configured to receive the power signature signal when the target electronic device is locally powered off.

4. The apparatus of claim 1, wherein the target electronic device is configured to be disposed relative to a package positioner, the package positioner configured to orientate the sealed package to a pre-determined orientation based on the power signature signal.

5. The apparatus of claim 1, wherein the excitation signal includes at least one of a Radio Frequency (RF) signal, an electromagnetic interference pulse, a white noise signal, a side-band signal, and a frequency-swept signal.

6. The apparatus of claim 1, wherein the power signature detector is configured to receive an electromagnetic (EM) emission signal associated with the target electronic device in response to the excitation signal.

7. The apparatus of claim 1, wherein the power signature detector includes a set of antennas, at least one antenna from the set of antennas configured to detect an EM emission signal associated with the target electronic device in a pre-determined orientation in response to the excitation signal.

8. The apparatus of claim 1, wherein the power signature detector includes a plurality of antennas spatially distributed substantially in a plane parallel to a plane of the sealed package.

9. The apparatus of claim 1, wherein the processor is configured to send a signal to the power signature detector such that a frequency bandwidth of the power signature signal corresponds to a frequency bandwidth of the excitation signal.

10. The apparatus of claim 1, wherein the processor is configured to determine the reference power signature signal via crowd sourcing or machine learning, the reference power signature signal is associated with a plurality of reference devices.

11. A method, comprising:
receiving a power signature signal associated with a target device that is disposed within a sealed package and excited by an excitation signal;
extracting a first characteristic of the power signature signal;
retrieving a reference power signature signal associate with a reference device, the reference power signature signal having a second characteristic, the reference device being a pre-determined trusted device or a pre-determined counterfeit device;
comparing the first characteristic of the power signature signal with the second characteristic of the reference power signature signal to determine a counterfeit status of the target device; and
sending, to a user interface, a notification signal indicative of the counterfeit status of the target device.

12. The method of claim 11, wherein the receiving includes receiving the power signature signal when the target electronic device is locally powered off and the target device is excited by the excitation signal.

13. The method of claim 11, wherein the excitation signal includes at least one of a Radio Frequency (RF) signal, an electromagnetic interference pulse, a white noise signal, a side-band signal, and a frequency-swept signal.

14. The method of claim 11, wherein the power signature signal is received from a power signature detector that (1) receives an electromagnetic (EM) emission signal associated with the target electronic device in response to the excitation signal, and (2) generates the power signature signal based on the EM emission signal.

15. The method of claim 11, wherein the power signature signal is received from a power signature detector that having a set of antennas including at least one antenna that detects an EM emission signal associated with the target electronic device in a pre-determined orientation in response to the excitation signal.

16. The method of claim 11, wherein the power signature signal is received from a power signature detector includes a plurality of antennas distributed spatially substantially in a plane parallel to a plane of the sealed package.

17. The method of claim 11, further comprising:
sending a signal such that a frequency bandwidth of the power signature signal corresponds to a frequency bandwidth of the excitation signal.

18. The method of claim 11, wherein the target device includes an analog electronic component.

19. The method of claim 11, wherein the target device is configured to be disposed relative to a package positioner, the package positioner configured to orientate the sealed package to a pre-determined orientation based on the power signature signal.

20. A system, comprising:
a power signature detector having a set of antennas, at least one antenna from the set of antennas configured to detect an electromagnetic (EM) emission signal associated with a target electronic device in response to the excitation signal,
the power signature detector configured to generate a power signature signal based on the EM emission signal associated with the target electronic device; and
a processor configured to be operatively coupled to the power signature detector, the processor configured to receive the power signature signal and extract a characteristic of the power signature signal,
the processor configured to compare the characteristic of the power signature signal with a characteristic of a reference power signature signal to determine a counterfeit status of the target electronic device, and
the processor configured to send to a user interface a notification signal associated with the counterfeit status of the target electronic device.
